(19) United States
(12) Patent Application Publication
(10) Pub. No.: US 2018/0351061 A1
(43) Pub. Date: Dec. 6, 2018

(54) CARRIER AND LIGHT EMITTING DEVICE

(71) Applicant: Everlight Electronics Co., Ltd., New Taipei City (TW)

(72) Inventors: Chien-Nan Liu, New Taipei City (TW); Yung-Chieh Chen, New Taipei City (TW); Chung-Chuan Hsieh, New Taipei City (TW)

(73) Assignee: Everlight Electronics Co., Ltd., New Taipei City (TW)

(21) Appl. No.: 16/039,246

(22) Filed: Jul. 18, 2018

Related U.S. Application Data
(63) Continuation-in-part of application No. 15/859,858, filed on Jan. 2, 2018.
Application No. 15/859,858 is a continuation of application No. 15/441,644, filed on Feb. 24, 2017, now Pat. No. 9,905,742.
Application No. 15/441,644 is a division of application No. 14/720,230, filed on May 22, 2015, now Pat. No. 9,640,733.
(60) Provisional application No. 62/535,246, filed on Jul. 21, 2017.
(60) Provisional application No. 62/590,285, filed on Nov. 23, 2017.
(60) Provisional application No. 62/613,056, filed on Jan. 3, 2018.

(30) Foreign Application Priority Data
May 23, 2014 (TW) 103118060
Feb. 3, 2015 (TW) 104103527

(51) Int. Cl. H01L 33/62; H01L 23/00; H01L 33/48; H01L 33/56; H01L 33/38; H01L 33/60

(52) U.S. Cl. CPC H01L 33/62; H01L 24/97; H01L 2933/0066; H01L 2933/0033; H01L 33/486; H01L 2933/005; H01L 33/56; H01L 2933/0058; H01L 2933/0016; H01L 33/38; H01L 33/60; H01L 33/483

(57) ABSTRACT

The present invention provides a carrier, including: at least one electrode portion, each electrode portion having an electrode portion cross section; and a housing having a housing cross section, the housing covering at least a part of the at least one electrode portion, where the housing cross section or the electrode portion cross section may include at least a curved surface; a reflective concave cup for exposing a part of the electrode portion, the reflective concave cup has, on its outer side wall, at least a plastic block protruding outward and matching a material feeding hole of a fabrication mold for fabricating the reflective concave cup, and thus the production yield and quality of the reflective concave cup are improved.

### TECHNICAL FIELD

The present invention relates to a carrier frame for a semiconductor element, and more particularly, to a carrier and a light emitting device fabricated therefrom.

### BACKGROUND

Light emitting diodes have advantages such as a long service life, a small volume, high resistance to shock, low heat generation and low power consumption, so they have been widely used in indicators or light sources in household appliances and various other appliances. In recent years, the light emitting diodes have developed towards multicolor and high brightness, so applications thereof have been extended to large-sized outdoor signboards, traffic signal lamps and related fields. In the future, it is even possible that the light emitting diodes will become mainstream illumination light sources having both power-saving and environmental protection functions. To impart the light emitting diodes with better reliability, most of the light emitting diodes are subjected to a packaging process to form durable light emitting devices.

The carrier of the light emitting device manufactured in the prior art includes a metal frame and a reflective concave cup. The reflective concave cup is provided with a light emitting diode chip in its inner cavity, and the reflective concave cup is generally a plastic piece. Specifically, the metal frame has a gap thereon. In the process of fabricating the reflective concave cup, a molten plastic is injected via the gap from bottom to up, forming the reflective concave cup on the metal frame.

However, due to the fact that the reflective concave cup in prior art is formed by injecting the plastic via the gap of the frame from bottom to up, there are many variations in the process, for example, bubbles in the molten plastic cannot be easily eliminated, resulting in a plurality of voids on the formed reflective concave cup. As a result, the reflective concave cup is weakened in terms of strength and can be easily deformed and damaged by external forces.

Moreover, in recent years, a dicing-type carrier frame has been developed by a person in the art to which the present invention belongs. Such a carrier frame is used for separate light emitting devices which are formed by molding a plastic body on a metal sheet, then performing a die bonding process, a wire bonding process and a packaging process, and then dicing the metal sheet, the plastic and the plastic body away simultaneously. However, a large amount of plastic and metal dusts tend to be produced during the dicing process, which seriously contaminate surfaces of final products and thus degrade the reliability of the products. Additionally, this process does not allow for a lit-on test prior to the packaging process, and measurements can only be made after the final products are singulated. However, the final products that have been singulated are piled and scattered, and machine measurements on them can only be made after orientation and direction adjustments. This requires use of additional instruments and is time consuming

### SUMMARY

In view of the aforesaid problem, the present invention provides a carrier capable of improving strength of a reflective concave cup, and the carrier frame has a pre-separated carrier mechanically coupled to the frame, thereby facilitating quick release of materials subsequent to die bonding, wire bonding, and packaging. Meanwhile, in the carrier frame of the present invention, each carrier is electrically isolated, so that after a light emitting diode is die bonded and wire bonded to the carrier, an electrical measurement may be performed before the release of materials.

In a first aspect, the present invention provides a carrier, including:

at least one electrode portion, each electrode portion having an electrode portion cross section; and

a housing having a housing cross section, the housing covering at least a part of the at least one electrode portion;

where the housing cross section or the electrode portion cross section may include at least a curved surface;

a reflective concave cup for exposing a part of the electrode portion;

the reflective concave cup has, on its outer side wall, at least a block protruding outward and matching a material feeding hole of a fabrication mold for fabricating the reflective concave cup.

For the carrier of the present invention, the reflective concave cup thereof has, on its outer side wall, at least a block protruding outward and matching a material feeding hole of a fabrication mold for fabricating the reflective concave cup, that is, the reflective concave cup is formed by way of material feeding on the side wall. After the injection molding is completed, the fabrication mold is removed, and a block is formed at a position corresponding to the material feeding hole of the fabrication mold of the reflective concave cup, and thus defects such as voids inside the reflective concave cup may be reduced, thereby improving the strength of the reflective concave cup.

In a second aspect, the present invention provides a carrier including:

at least one electrode portion, each electrode portion having an electrode portion cross section; and

a housing having a housing cross section, the housing covering at least a part of the at least one electrode portion;

where the housing cross section is not aligned with the electrode portion cross section;

a reflective concave cup for exposing a part of the electrode portion;

the reflective concave cup has, on its outer side wall, at least one block protruding outward and matching a material feeding hole of a fabrication mold for fabricating the reflective concave cup.

For the carrier of the present invention, the reflective concave cup thereof has, on its outer side wall, a block protruding outward and matching a material feeding hole of a fabrication mold for fabricating the reflective concave cup, that is, the reflective concave cup is formed by way of material feeding on the side wall. After the injection molding is completed, the fabrication mold is removed, and a block is formed at a position corresponding to the material feeding hole of the fabrication mold of the reflective concave cup, and thus defects such as voids inside the reflective concave cup may be reduced, thereby improving the strength of the reflective concave cup.

### BRIEF DESCRIPTION OF DRAWINGS

In order to make the above purpose, features and advantages of the present invention more apparent and easy to understand, specific embodiments of the present invention will be described in detail below with reference to the accompanying drawings, in which:

FIG. 1 is a partial schematic view of an embodiment of a carrier frame according to the present invention;

FIG. 2 is a partial schematic view of a conductive support used in the carrier frame of FIG. 1;

FIG. 3 is a partial schematic view of the carrier frame of FIG. 1 after a plastic body is formed;

FIG. 4A and FIG. 4B are partial schematic views of the carrier frame of FIG. 1 after the residual material is removed;

FIG. 5 is a partial schematic view of another embodiment of the carrier frame according to the present invention;

FIG. 6 is a top view of a light emitting device according to an embodiment of the present invention;

FIG. 7 is a top view of a light emitting device according to another embodiment of the present invention;

FIG. 8 is a top view of a light emitting device according to a further embodiment of the present invention;

FIG. 9 is a top view of a light emitting device according to yet another embodiment of the present invention;

FIG. 10 is a top view of a light emitting device according to yet a further embodiment of the present invention;

FIG. 11 is a top view of a light emitting device according to yet a further embodiment of the present invention;

FIG. 12A to FIG. 12D are respectively a top view, a full cross-sectional view taken along the front-to-back direction, a full cross-sectional view taken along the left-to-right direction, and a partially enlarged view of a carrier frame according to an embodiment of the present invention;

FIG. 13A to FIG. 16 are schematic views illustrating steps of a method for manufacturing a carrier frame according to an embodiment of the present invention;

FIG. 17A to FIG. 17D are respectively a top view, a full cross-sectional view taken along the front-to-back direction, a full cross-sectional view taken along the left-to-right direction, and a partially enlarged view of a carrier frame according to an embodiment of the present invention;

FIG. 18A to FIG. 22 are schematic views illustrating steps of a method for manufacturing a carrier frame according to an embodiment of the present invention;

FIG. 23 is a schematic structural view of a carrier frame according to an embodiment of the present invention;

FIG. 24 is a top view of a structure of a reflective concave cup in a carrier frame according to an embodiment of the present invention;

FIG. 25 is a schematic structural view with a light emitting diode chip provided on a carrier frame according to an embodiment of the present invention; and

FIG. 26 is a side sectional view corresponding to FIG. 25.

Explanation to reference signs of elements in the drawings:
100, 100′, 100″: Carrier frame
110: Carrier
111: Housing
111A: Housing cross section
111R: Rounded corner
112: Electrode portion
112A: Wing portion
112A1: Central outward protruding area, central area
112A2: Outer edge area, edge area, electrode portion cross section
112B: Inner side surface
112C: Connecting surface
1121: Recess
120: Frame
121: Supporting portion
122: Channel region
123: Side portion
130: Depletion region
131: Gap
132: First through groove
133: Second through groove
140: Extending portion
141: Lock hole
142: Step portion
143: Groove
150: Plastic body
151: Residual material
160: Conductive support
20: Reflective concave cup
200: Plastic block
201: Top surface
202: Groove
31, 32: Conductive circuit
311, 321: First electrode portion
312, 322: Second electrode portion
310, 320: Accommodating region
41, 42: Light emitting diode chip
411, 412, 421, 422: Lead

### DESCRIPTION OF EMBODIMENTS

A carrier frame of the present invention includes a frame and a carrier, and the carrier includes a housing and at least one electrode portion. In the present invention, the frame includes at least one supporting portion and is engaged with the carrier by way of mechanical coupling so that the carrier is supported on the frame. In a specific embodiment of the present invention, the housing may have a concave portion mating with the supporting portion, and the carrier is supported on the frame through an engagement between the supporting portion and the concave portion. The position of the concave portion is not particularly limited in the present invention, and the concave portion may be located at a side surface or at a border between a bottom surface and the side surface of the carrier. A corresponding supporting portion goes deep into the carrier or is only positioned on the bottom surface of the carrier with a half thereof being exposed outside.

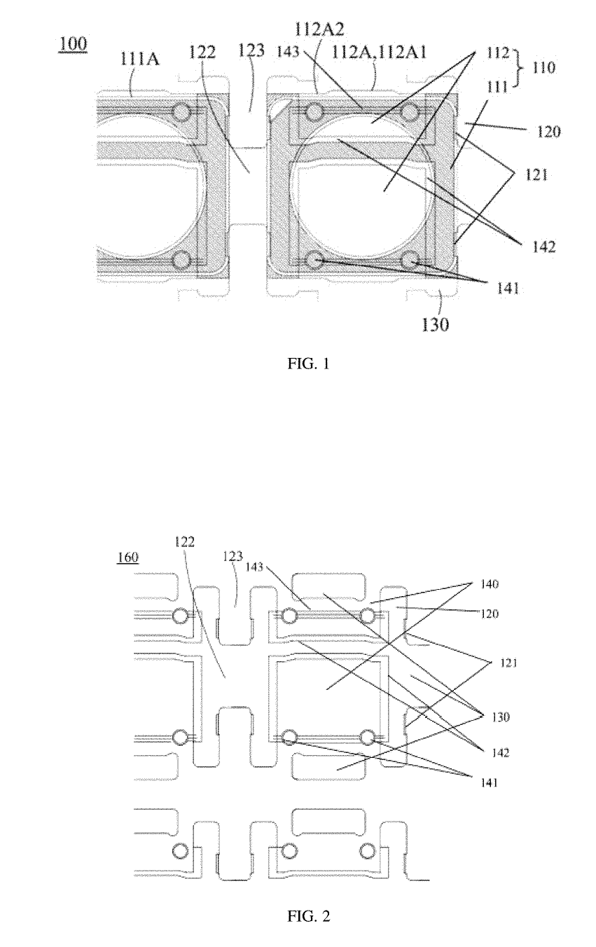

FIG. 1 is a partial schematic view of an embodiment of a carrier frame according to the present invention. As shown in FIG. 1, a carrier frame 100 includes a carrier 110 and a frame 120, where the carrier 110 includes a housing 111 and two electrode portions 112. The frame 120 includes a plurality of supporting portions 121. As shown in FIG. 1, the frame 120 beneath the carrier frame 100 includes four supporting portions 121, and four concave portions (corresponding to positions of the supporting portions 121) are formed at the border between a side surface and the bottom surface of the housing 111 so that each of the four supporting portions 121 is positioned on the bottom surface of the carrier 110 with a half thereof being exposed outside. In an embodiment, the carrier 110 further includes a reflective concave cup for exposing a part of the electrode portion 112. The electrode portion 112 extends outward from the reflective concave cup via the housing 111 to the outside.

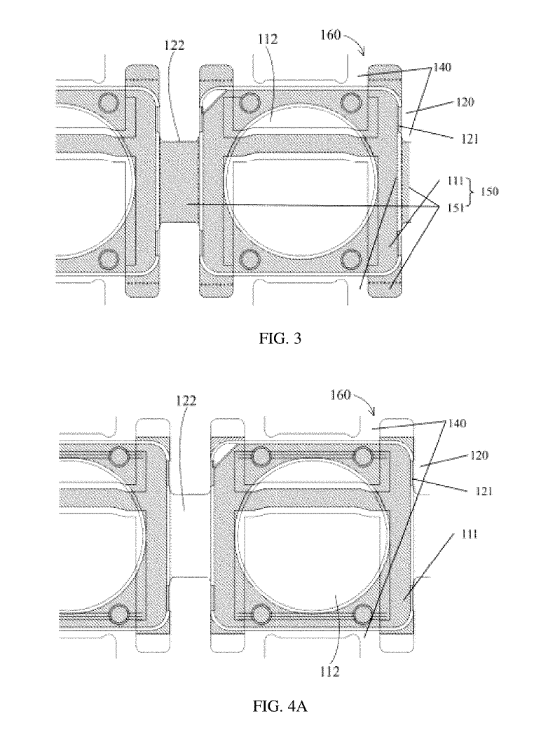

The frame 120 may also have a channel region 122 and a side portion 123, and the channel region 122 is disposed on the side portion 123. The channel region 122 is a penetrated region that allows a plastic body 150 (as shown in FIG. 3) described hereinafter to flow therethrough, and the supporting portion 121 is also disposed on the side portion 123.

Additionally, in the present invention, a lock hole, a groove (a linear slit on a surface of each of the electrode portions) and a step may also be added in each of the electrode portions 112. The mechanical binding force between the housing and each of the electrode portions in the carrier may be increased due to the lock hole, the groove and the step. As shown in FIG. 1, each of the two electrode portions 112 in the carrier 110 includes two lock holes 141 and three grooves 143, and steps 142 are provided on edges of the two electrode portions 112 that are enclosed by the housing 111, thereby increasing the binding strength between the housing 111 and each of the electrode portions 112.

Each carrier in the carrier frame of the present invention is supported on the frame via the mechanical engagement between the concave portion and each of the supporting portions, and the electrode portions of different carriers are electrically isolated from each other. Thus, after light emitting devices are subjected to a die bonding process, a wire bonding process and a packaging process later, an electrical measurement may be made to the light emitting devices that have not been singulated (i.e., the light emitting devices are still supported on the frame in an orderly way). Since the light emitting devices are arranged orderly, time required for orientation and direction adjustments for devices may be eliminated and the production speed of the light emitting devices may be greatly improved.

The carrier frame of the present invention may be fabricated by the following method. First, a conductive support is provided. The conductive support includes a frame, at least one depletion region and at least one extending portion, where the frame includes at least one supporting portion. Then, a plastic body is formed on the conductive support, which covers at least a part of the extending portion and at least a part of the supporting portion and fills at least a part of the depletion region. Subsequently, the part of the extending portion exposed outside the housing and the part of the plastic body filled in the depletion region are respectively removed so as to form the carrier. In particular, after the two removing steps, the housing in the carrier is formed by the remaining plastic body, and each of the electrode portions in the carrier is formed by the extending portion remained on the plastic body.

Hereinafter, a process for fabricating the carrier frame 100 of FIG. 1 will be detailed with reference to FIG. 2 to FIG. 4A. First, a conductive support 160 as shown in FIG. 2 is provided. The conductive support 160 includes a frame 120, a plurality of depletion regions 130 and a plurality of extending portions 140. The frame 120 also includes a plurality of supporting portions 121, and each of the extending portions 140 includes a plurality of lock holes 141, grooves 143 and steps 142. Finally, part of the extending portions 140 exposed outside the housing are removed to form the carrier frame 100 of FIG. 1.

In the present invention, the conductive support may be made of a metal sheet, including a pure metal sheet, an alloy sheet, and a metal composite sheet, and the composite sheet is preferably a metal sheet cladded with a conductive layer having a relatively high resistance to oxidation or a relatively high solder binding force (e.g., a silver-plated copper sheet, or the like). The frame, the extending portions and the depletion regions are formed in an appropriate way. When the conductive support is made of a metal sheet, the frame, the extending portions and the depletion regions may be preferably formed through a stamping process; however, they may also be formed through a dicing process or a mold casting process. Moreover, if the conductive support has insufficient conductivity, a conductive layer (not shown) may be formed on the conductive support after the conductive support is provided (the conductivity of the conductive layer is higher than that of the conductive support) so as to increase reliability of results of a subsequent test. The material of the conductive layer may include a material having high conductivity (e.g., silver, or the like).

After the conductive support is provided, a plastic body is then formed on the conductive support. The way in which the plastic body is formed is not limited. For Example, the plastic body may be formed through transfer molding (Transfer Moulding), injection molding, etc. The material of the plastic body is not limited either, which may be selected from a common plastic composite currently used in the industry, e.g., epoxy (Epoxy) compositions, silicon (Silicon) compositions, polyphthalamide (Polyphthalamide) compositions, or polyethylene terephthalate (Polyethylene terephthalate) compositions. In a specific embodiment of the present invention, an epoxy composition is used, and the plastic body is formed by means of the transfer molding. In an embodiment, the plastic body may be a thermosetting material and may further include a reflective material, e.g., titanium dioxide (TiO2), zinc oxide (ZnO) or boron nitride (BN).

Next, a plastic body 150 is formed on the conductive support 160 as shown in FIG. 3. The plastic body 150 covers a part of each of the extending portions 140 and completely covers all of the lock holes 141 and grooves 143. The plastic body 150 also fills a part of each of the depletion regions 130 (the part of the depletion region 130 above and below the extending portion 140 is not filled) and completely covers all of the supporting portions 121. The plastic body 150 also fills the channel region 122 and is integrally formed with another adjacent plastic body 150.

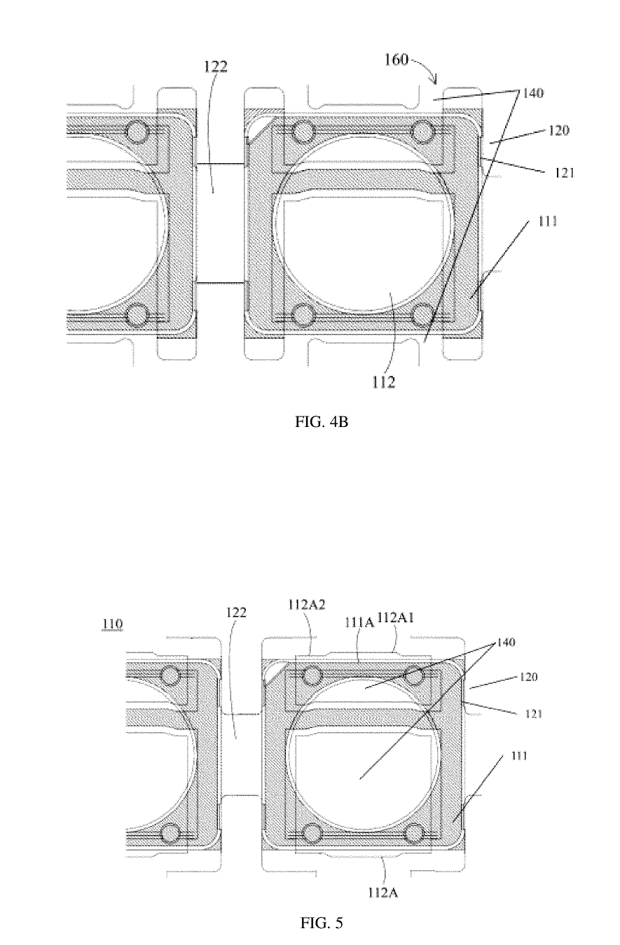

Further, the raw material of the plastic body 150 will be filled in a mold cavity of the mold and the depletion regions during its formation. In this step, the housing 111 and the residual material 151 are still integrated. The scope of the residual material 151 is defined depending on application of follow-up products. As shown in FIG. 3, what denoted by dotted lines is the residual material 151 defined in this embodiment. Thereafter, the defined residual material 151 is removed as shown in FIG. 4A, thereby forming the housing 111 in the carrier 110.

If the channel region 122 is filled with the plastic body 150, the residual material 151 may be removed by at least two steps, e.g., by firstly removing the residual material 151 filled in the channel region 122 and then removing the residual material 151 filled in the depletion regions 130 or vice versa. This may simplify an arrangement of cutters for removing the residual material 151 in each step so that the cutters have a sufficient distance therebetween and more desirable strength.

Finally, the part of the extending portion 140 exposed outside the housing 111 is removed to form the carrier frame 100 as shown in FIG. 1. Before the part of the extending portion 140 is removed, a part of the frame 120 at two sides of the channel region 122 is removed optionally with a cutter having a length larger than that of the channel region 122 so as to thoroughly remove the residual material 151 possibly left in the channel region 122, therefore, damages to the electrode portions 112 or light emitting diode chips may be avoided by preventing the residual material 151 from falling off onto the electrode portions 112 or the light emitting diode chips. After the part of the frame 120 at two sides of the channel region 122 is removed, the length of the channel region 122 will be increased as shown in FIG. 4B.

Therefore, the manufacturing method of this embodiment may be optionally performed at two or more removing steps for the conductive support 160, and may also be performed at two or more removing steps for the plastic body 150 (the residual material 151).

In the present invention, the residual material 151 and the part of the extending portion 140 are removed separately. In particular, the order in which the residual material 151 and the part of the extending portion 140 are removed is not particularly limited as long as they are separately removed. For example, all the parts of the extending portions 140 may be simultaneously removed after all the residual material 151 is simultaneously removed, or all the residual material 151 may be removed after all the parts of the extending portions 140 are simultaneously removed, or a part of the residual material 151 and the part of the extending portion 140 may be removed alternately in different stages. The way in which the removing steps are performed is not limited, and the removing steps may be accomplished for example through a dicing process or a stamping process, but preferably through the stamping process. The stamping process is taken as an example in the embodiments of the present invention.

The tools and the working strength may be adjusted depending on mechanical properties of the parts to be removed in the present invention. In particular, the respective removing steps may avoid drawbacks resulting from removing different materials simultaneously, e.g., plane defects or damages to the removing tools (cutters) due to non-uniform stresses. Additionally, dusts of the plastic body generally tend to be produced during the removal of the part of the plastic body as compared to the removal of the part of the extending portion. These dusts can only be removed with a strong external force, e.g., through strong air blowing, jittering, or ultrasonic waves. If the cleaning step is to be performed after the residual material and the part of the extending portion are simultaneously removed, it is possible that the action force between the carrier and the frame is insufficient to avoid falling off of the material. Thus, in the present invention, the cleaning step (i.e., the cleaning of the plastic body) is preferably performed after the residual material is removed while before the part of each of the extending portions is removed. This may enhance the connection strength between the carrier and the frame by means of the extending portions so as to avoid falling off of the material during the cleaning step, and finally the part of each of the extending portions is removed.

After the removing of the parts of the extending portions, at least one electrode portion cross section will be formed on each of the electrode portions of the carrier; and after the removing of the residual material, a housing cross section will be formed on the housing of the carrier. In the present invention, the electrode portion cross section and the housing cross section may be located on the same surface or different surfaces of the carrier depending on conditions such as the safety specification of the final product or the customer requirements. Further, in a case where the electrode portion cross section and the housing cross section are located on the same surface of the carrier, the electrode portion cross section and the housing cross section may be aligned with each other (i.e., form a flat surface) or may not be aligned with each other (i.e., not form a flat surface).

As shown in FIG. 1, each of the electrode portions 112 has a wing portion 112A exposed outside the housing, and the wing portion 112A includes a central outward protruding area (or referred to as a central area) 112A1 and two outer edge areas (or referred to as edge areas) 112A2. In the embodiment as shown in FIG. 1, each of the edge areas 112A2 includes an electrode portion cross section; and these electrode portion cross sections are aligned with a part of the housing cross section 111A of the housing 111; in this case, the carrier has a relatively flat appearance. However, as shown in FIG. 5, the wing portion 112A of each of the electrode portions 112 includes a central outward protruding area 112A1 and two outer edge areas 112A2, and the electrode portion cross section of each of the electrode portions 112 is not aligned with the housing cross section 111A of the housing 111; and in this case, each of the electrode portions 112 has an additional lateral area that can increase the binding force with the solder so as to increase the component bonding strength of the light emitting device after the subsequent component bonding process.

Moreover, in a case where the conductive support is a metal composite sheet with an antioxidant layer, a cross section uncovered with the antioxidant layer will be formed on the electrode portion cross section. In the present invention, the cross section uncovered with the antioxidant layer is preferably formed integrally with the central area of each of the electrode portions. During the subsequent component bonding process, the solder may climb along the side surface of the wing portion and cover the side surface, and in this case, at least a part of the cross section uncovered with the antioxidant layer may be covered by the solder, and the probability that the cross section portion is oxidized may be reduced. Additionally, the cross section uncovered with the antioxidant layer and the surface of the adjacent central area are at the same side, and preferably form a continuous surface so as to reduce sharp tips or rough edges for each of the electrode portions. Otherwise, the sharp tips or rough edges would cause wear and tear of the subsequent processing machine, and a charge accumulation effect even will occur at the sharp tips or the rough edges to influence the reliability of the final product.

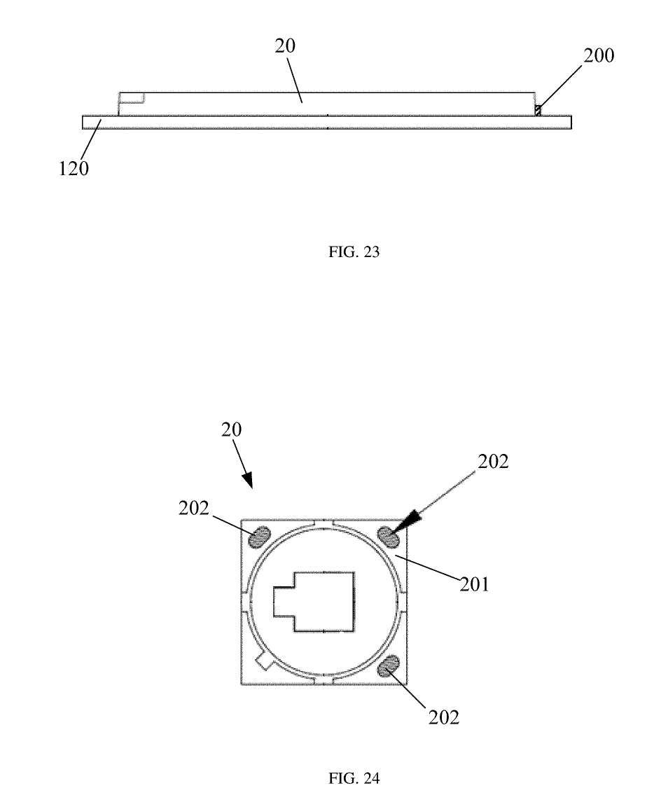

FIG. 23 is a schematic structural view of a carrier frame according to an embodiment of the present invention. In an embodiment of the present invention, the reflective concave cup 20 has, on its the outer side wall, at least one plastic block 200 protruding outward and matching a material feeding hole of a fabrication mold (not shown in the drawing) for the reflective concave cup 20. That is to say, in the present embodiment, the reflective concave cup 20 is formed by the way of material feeding on the side wall. The material of the reflective concave cup 20 is specifically a thermoplastic plastic, and the reflective concave cup 20 may be a white reflective concave cup, or may be of another color, but the present invention is not limited thereto, and the reflective concave cup 20 may be configured according to actual needs. In a specific implementation, the plastic block 200 may be one, or may be more than one.

During a specific fabrication, the fabrication mold corresponding to the reflective concave cup 20 is placed on the frame 120, where the fabrication mold has a material feeding hole thereon. In a specific implementation, the mold has an upper mold and a lower mold, where the upper mold has a first notch, and the lower mold has a second notch. When the upper and lower molds are engaged together, the first notch and the second notch jointly define the above-mentioned material feeding hole. A molten plastic is injected into the material injecting hole, and the reflective concave cup 20 may be formed on the frame 120 after a curing process, and then the mold is removed. A plastic block 200 matching the shape of the material feeding hole is formed on the outer side wall of the fabricated and formed reflective concave cup 20 at a position corresponding to the material feeding hole of the mold.

For the carrier provided in this embodiment, the reflective concave cup 20 thereof, has on its outer side wall, a plastic block 200 protruding outward and matching a material feeding hole of a fabrication mold of the reflective concave cup 20, that is, the reflective concave cup 20 is formed by the way of material feeding on the side wall. After the injection molding is completed, the fabrication mold is removed, and a plastic block is formed at a position corresponding to the material feeding hole of the fabrication mold of the reflective concave cup 20, defects such as voids inside the reflective concave cup 20 may be reduced, thereby improving the strength of the reflective concave cup 20. A configuration may be made according to actual needs.

The plastic block 200 may be specifically located at the bottom of the outer side wall of the reflective concave cup 20, so that the injection molding of the material is more convenient and it is more advantageous to form the reflective concave cup 20.

The present invention also provides a light emitting device fabricated from the carrier frame of the present invention, and the light emitting device includes a carrier, a light emitting diode chip and a package. The light emitting diode chip is carried within the carrier and covered by the package. The material of the package in the present invention may be a plastic composite of epoxy resins or silicone. Moreover, for the light emitting device of the present invention, a fluorescent material may be added into the package as desired, and examples of the fluorescent material include: an aluminate fluorescent material (e.g., a doped yttrium aluminum oxide compound, a doped lutetium aluminum oxide compound, a doped terbium aluminum oxide compound, or a combination thereof), a silicate fluorescent material, a sulfide fluorescent material, an oxynitride fluorescent material, a nitride fluorescent material, a fluoride fluorescent material, or a combination thereof.

The light emitting device of the present invention may be fabricated in the following way. First, a carrier frame as described above is provided. Then, a light emitting diode chip is provided and die bonded and wire bonded into the reflective concave cup of the carrier. Thereafter, the reflective concave cup is filled with a package so as to package and encapsulate the light emitting diode chip, that is, a light emitting device on the frame is formed. Finally, the light emitting device is separated from the frame (i.e., the carrier frame is separated from the frame, for example, through extrusion) to form a separate light emitting device.

A plurality of light emitting diode chips may also be provided within the carrier in the present invention, and these light emitting diode chips may emit lights of the same spectrum or different spectrums. After the light emitting diode chips are fixed, the wire bonding process may be performed to electrically connect the light emitting diode chips with the electrode portions. Other electronic elements, such as a Zener diode or a thermistor, may also be provided depending on requirements of the final product.

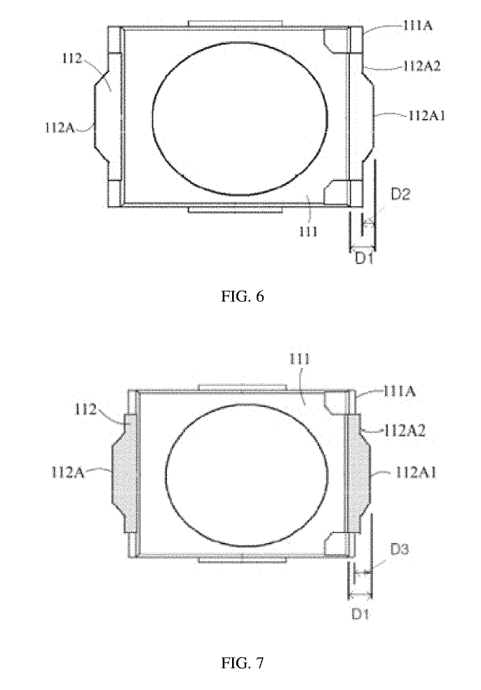

Reference may be made to FIG. 6 which is a top view of a light emitting device according to an embodiment of the present invention. The wing portion 112A of each of the electrode portions 112 has a central area 112A1 and two edge areas 112A2, and the central area 112A1 protrudes from the two edge areas 112A2. The wing portion 112A protrudes out of the housing cross section 111A of the housing 111 so that the central area 1112A1 of the wing portion 112A of each of the electrode portions 112 is not coplanar with the housing cross section 111A of the housing 111. An interval D1 is the distance between the central area of the wing portion 112A of each of the electrode portions 112 and the inner side of the housing cross section 111A of the housing 111, and the interval D1 is about 0.1 mm. An interval D2 is the distance between the central area 112A1 of the wing portion 112A of each of the electrode portions 112 and the outer side of the wing portion 112A of the housing 111 (i.e., the central area 112A1 of the wing portion 112A of each of the electrode portions 112 and the wing portion 112A of the housing 111), and the interval D2 is about 0.05 mm.

Reference may be made to FIG. 7 which is a top view of a light emitting device according to another embodiment of the present invention. The wing portion 112A of each of the electrode portions 112 has a central area 112A1 and two edge areas 112A2, and the wing portion 112A protrudes out of the housing cross section 111A of the housing 111 so that the wing portion 112A of each of the electrode portions 112 is not coplanar with the housing cross section 111A of the housing 111. An interval D1 is the distance between the central area of the wing portion 112A of each of the electrode portions 112 and the inner side of the housing cross section 111A of the housing 111, and the interval D1 is about 0.1 mm. An interval D3 is the distance between the central area 112A1 of the wing portion 112A of each of the electrode portions 112 and the outer side of the cross section 111A of the housing 111, and the interval D3 is about 0.075 mm.

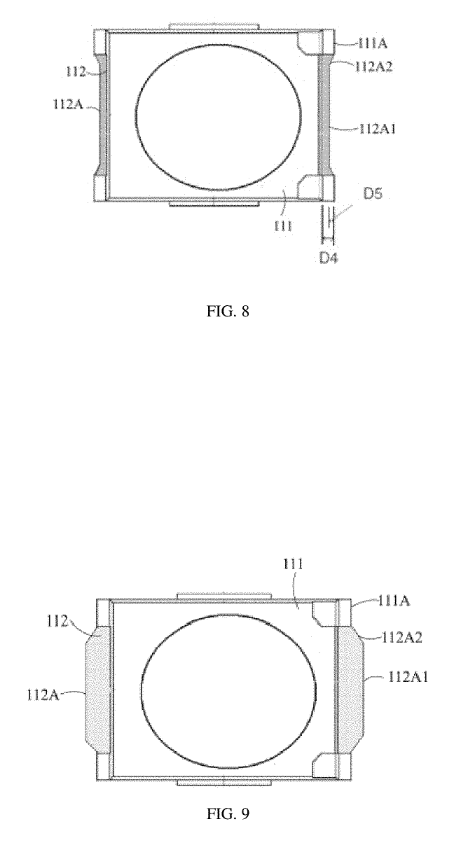

Reference may be made to FIG. 8 which is a top view of a light emitting device according to a further embodiment of the present invention. The wing portion 112A of each of the electrode portions 112 has a central area 112A1 and two edge areas 112A2, the central area 112A1 is recessed from the two edge areas 112A2, and electrode portion cross sections of the two edge areas 112A2 are sloping surfaces. The wing portion 112A is recessed into the cross section 111A of the housing 111 so that the wing portion 112A of each of the electrode portions 112 is not coplanar with the cross section 111A of the housing 111. An interval D4 is the distance between the outer side and the inner side of the cross section 111A of the housing 111, and the interval D4 is about 0.05 mm. An interval D5 is the distance between the central area of the wing portion 112A of each of the electrode portions 112 and the outer side of the cross section 111A of the housing 111, and the interval D5 is about 0.025 mm.

Reference may be made to FIG. 9 which is a top view of a light emitting device according to yet another embodiment of the present invention. The wing portion 112A of each of the electrode portions 112 has a central area 112A1 and two edge areas 112A2, the central area 112A1 protrudes out of the two edge areas 112A2, and electrode portion cross sections of the two edge areas 112A2 are sloping surfaces. The wing portion 112A protrudes out of the cross section 111A of the housing 111 so that the wing portion 112A of each of the electrode portions 112 is not coplanar with the cross section 111A of the housing 111.

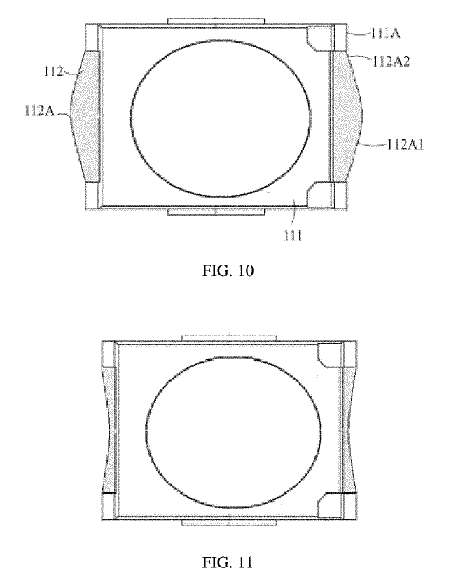

Reference may be made to FIG. 10 which is a top view of a light emitting device according to yet a further embodiment of the present invention. The wing portion 112A of each of the electrode portions 112 is a convex curved surface, i.e., the external surface of the central area and outlines (the electrode portion cross sections) of the edge areas together form a continuous convex curved surface. The wing portion 112A protrudes out of the cross section 111A of the housing 111 so that the wing portion 112A of each of the electrode portions 112 is not coplanar with the cross section 111A of the housing 111.

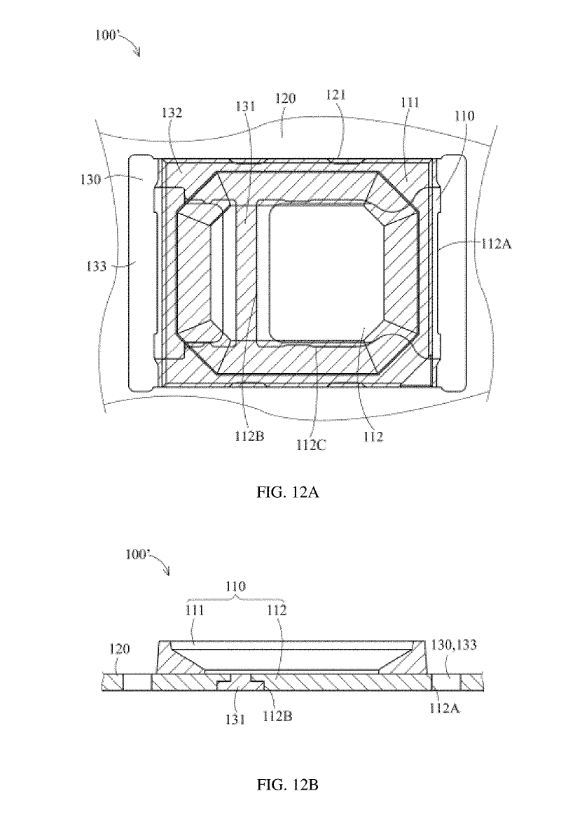

Reference may be made to FIG. 11 which is a top view of a light emitting device according to an embodiment of the present invention. The wing portion 112A of each of the electrode portions 112 is a concave curved surface, i.e., the external surface of the central area and the outlines (the electrode portion cross sections) of the edge areas together form a continuous concave curved surface. The wing portion 112A is recessed into the cross section 111A of the housing 111 so that the wing portion 112A of each of the electrode portions 112 is not coplanar with the cross section 111A of the housing 111.

For the reflective concave cup 20, it can be understood that the reflective concave cup 20 is used for accommodating the light emitting diode chip and reflecting the light emitted by the light emitting diode chip. That is, the light emitting diode chip is located in a concave cavity of the reflective concave cup 20. In a specific implementation, the reflective concave cup 20 may also be covered with a component such as a lens or the like. By providing a lens, the path of the light emitted by the light emitting diode chip may be changed.

In an embodiment of the present invention, the component such as the lens or the like is adhered to the top of the reflective concave cup 20 by adhesive. FIG. 24 is a top view of a reflective concave cup in a carrier frame according to an embodiment of the present invention. Reference may be made to FIG. 24, where a groove 202 for accommodating adhesive may be defined on the top surface 201 of the reflective concave cup 20, and by providing the groove 202, adhesion between the reflective concave cup 20 and the lens may be improved so that the connection is more reliable. When assembling, the adhesive is first injected into the groove 202 on a top surface of the reflective concave cup 20, and then the lens is adhered to the reflective concave cup 20 through the adhesive. In addition, the presence of the groove 202 serves to better limit the adhesive, preventing the adhesive from flowing freely and affecting the adhering effect and appearance of the light emitting device.

Specifically, there may be at least two grooves 202 that are arranged at intervals along the top surface of the reflective concave cup 20, so that the adhesion may be achieved at different positions, further improving the adhesion between the reflective concave cup 20 and the lens. With continued reference to FIG. 24, in the present embodiment, there are specifically three grooves 202. Of course, in other implementations, there may be two or more than three grooves 202.

The depth of the groove 202 may be set to 0.1 mm, so that not only the reliable connection between the reflective concave cup 20 and the lens can be ensured, but also the amount of the adhesive may be ensured, thereby avoiding the waste caused by excessive adhesive and guaranteeing fabrication costs.

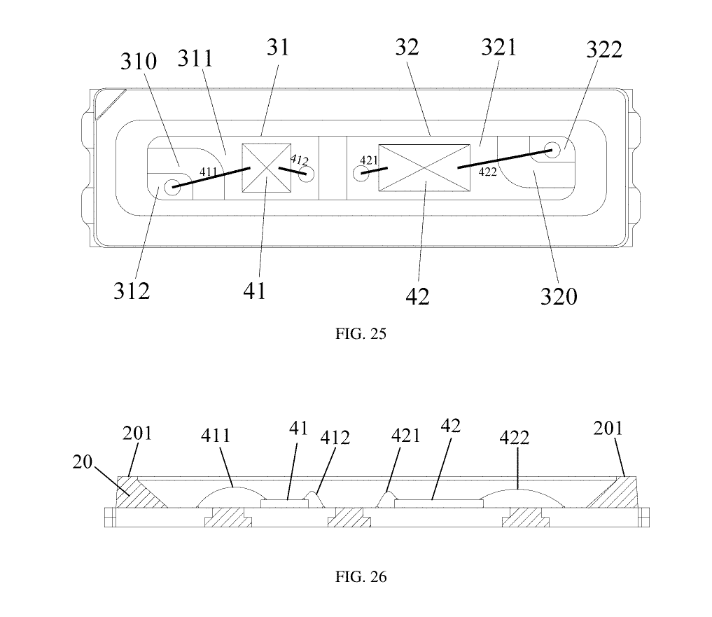

FIG. 25 is a schematic view of a carrier frame with a light emitting diode chip thereon according to an embodiment of the present invention. FIG. 26 is a side sectional view corresponding to FIG. 25. Reference may be made to FIG. 25 and FIG. 26, in an embodiment of the present invention, the carrier may include at least two conductive circuits, each of which is electrically independent. For each conductive circuit, each conductive circuit includes a first electrode portion and a second electrode portion, where the first electrode portion has an accommodating region where the second electrode portion is located. The first electrode portion is provided with a light emitting diode chip that is electrically connected to the first electrode portion and the second electrode portion, respectively.

It can be understood that for each conductive circuit, the polarity of the first electrode portion is opposite to that of the second electrode portion, for example, the first electrode portion is a positive electrode while the second electrode portion is a negative electrode, or the first electrode portion is a negative electrode while the second electrode portion is a positive electrode.

Reference may be made to FIG. 25 and FIG. 26, exemplarily, the carrier specifically includes two conductive circuits, respectively a conductive circuit 31 and a conductive circuit 32. The conductive circuit 31 and the conductive circuit 32 are electrically independent. The conductive circuit 31 on the left side of the drawing includes a first electrode portion 311 and a second electrode portion 312. The first electrode portion 311 has an accommodating region 310 thereon, and the second electrode portion 312 is located in the accommodating region 310. The first electrode portion 311 has a light emitting diode chip 41 thereon. The light emitting diode chip 41 is electrically connected to the first electrode portion 311 and the second electrode portion 312, respectively. Specifically, one end of the light emitting diode chip 41 is welded to the second electrode portion 312 through a lead 411, and the other end of the light emitting diode chip 41 is welded to the first electrode portion 311 through a lead 412. The conductive circuit 32 on the right side of the drawing includes a first electrode portion 321 and a second electrode portion 322. The first electrode portion 321 has an accommodating region 320, and the second electrode portion 322 is located in the accommodating region 320. The first electrode portion 321 has a light emitting diode chip 42 thereon, and the light emitting diode chip 42 is electrically connected to the first electrode portion 321 and the second electrode portion 322, respectively. Specifically, one end of the light emitting diode chip 42 is welded to the first electrode portion 321 through a lead 421, and the other end of the light emitting diode chip 42 is welded to the second electrode portion 322 through a lead 422.

In an embodiment of the present invention, for example, the light emitted by the light emitting diode chip 41 on the conductive circuit 31 at the left side is green light, and the light emitted by the light emitting diode chip 42 on the conductive circuit 32 at the right side is blue light. It should be noted that the color of the light specifically emitted by the light emitting diode chip is not limited in the present invention. In addition, the colors emitted by the light emitting diode chips on different conductive circuits may be the same or different, which is not limited in this embodiment.

By providing at least two conductive circuits on the carrier, each conductive circuit has a light emitting diode chip thereon. Since the conductive circuits are electrically independent from each other, not only a plurality of light emitting diode chips may be placed on the carrier, but also the light emitting diode chips located in different conductive circuits may be individually controlled, thereby making the control of the light emitting device more flexible and convenient.

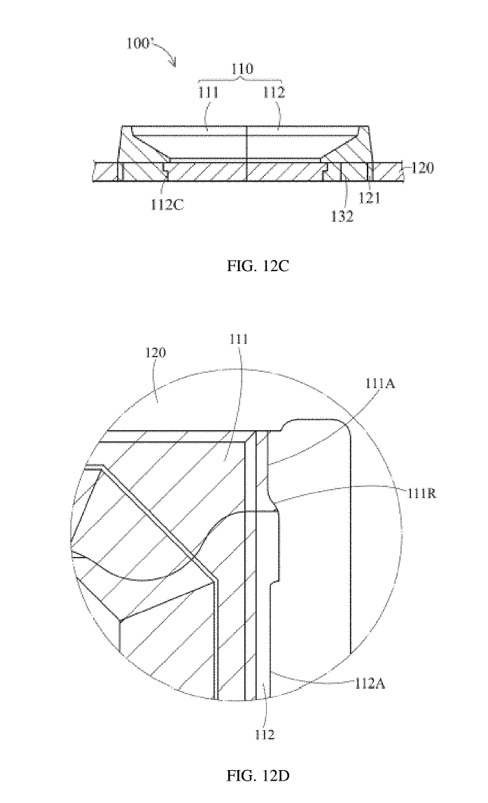

Reference may be made to FIG. 12A to FIG. 12D which are schematic views (i.e., a top view, a full cross-sectional view taken along the front-to-back direction, a full cross-sectional view taken along the left-to-right direction, and a partially enlarged view) of a carrier frame 100′ according to an embodiment of the present invention. The carrier frame 100′ is similar to the aforesaid carrier frame 100. That is, the carrier frame 100′ also includes a frame 120 and a carrier 110, where the frame 120 includes at least one supporting portion 121, the carrier 110 includes a housing 111 and at least one electrode portion 112, and the housing 111 is mechanically coupled to the frame 120 via the supporting portion 121. Thus, for the technical contents of the aforesaid elements, reference may be made to counterparts of the carrier frame 100.

Preferably, the at least one electrode portion 112 may be two electrode portions 112 spaced apart from each other, which serve as an anode terminal and a cathode terminal of the carrier 110. The two electrode portions 112 are surrounded by the frame 120, i.e., the two electrode portions 112 are located within a space surrounded by the frame 120 in itself. The two electrode portions 112 may be separated from the frame 120 by at least one depletion region 130 so that the two electrode portions 112 are not brought into contact with the frame 120 and thus are electrically isolated from the frame 120.

The supporting portion 121 of the frame 120 extends towards one of the two electrode portions 112, but is not brought into contact with the electrode portion 112. In this embodiment, there are four supporting portions 121 that are distributed at two sides of the electrode portions 112. The housing 111 may at least cover the supporting portions 121 and at least parts of the two electrode portions 112, and is at least disposed within a part of the depletion region 130. Thereby, the housing 111 is mechanically coupled to the frame 120 via the supporting portions 121, and the housing 111 is also mechanically engaged with the two electrode portions 112 so that the housing 111 and the two electrode portions 112 are be held within the frame 120 without falling off from the frame 120.

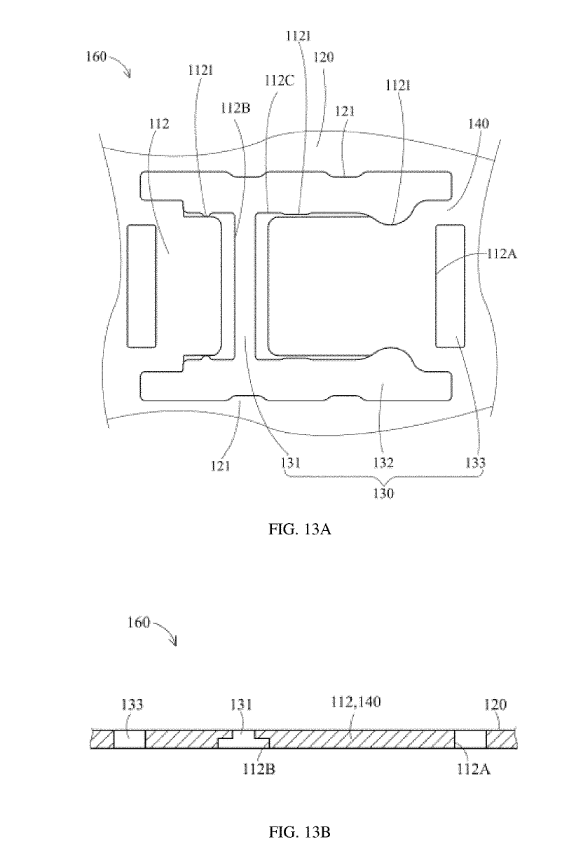

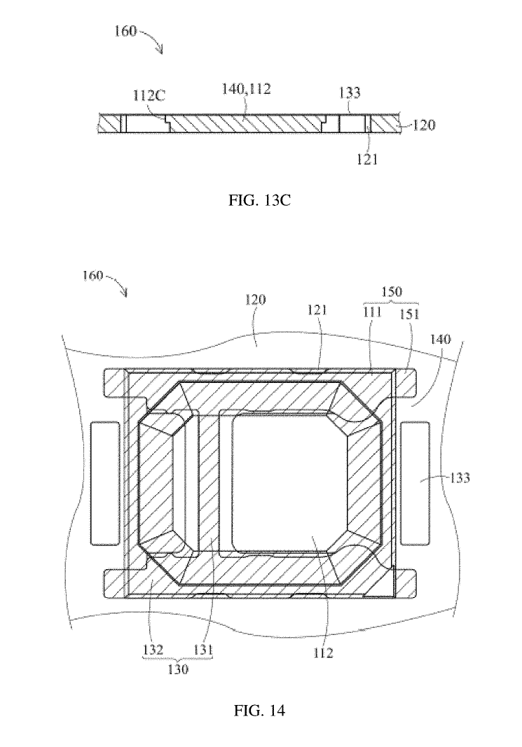

The shape features of the electrode portions 112 will be further described. Reference may be made to FIG. 13A, where each of the two electrode portions 112 has a wing portion 112A and an inner side surface 112B that are disposed opposite to each other (i.e., disposed oppositely), the wing portion 112A may be exposed outside the housing cross section 111A of the housing 111 (reference may be made to the aforesaid relevant descriptions of FIG. 6 to FIG. 11) and does not face the wing portion 112A of another electrode portion 112. Inner side surfaces 112B of the two electrode portions 112 may face each other, and at least parts of the two electrode portions 112 may be covered by the housing 111.

Each of the two electrode portions 112 further includes two connecting surfaces 112C disposed opposite to each other, and each of the connecting surfaces 112C connects the wing portion 112A with the inner side surface 112B. That is, an edge (e.g., a front edge) of the connecting surface 112C connects with an edge (i.e., a left edge) of the wing portion 112A, while another edge (e.g., a rear edge) of the connecting surface 112C connects with an edge (i.e., a left edge) of the inner side surface 112B. The wing portion 112A, the inner side surface 112B and the two connecting surfaces 112C may not be flat surfaces. That is, the wing portion 112A, the inner side surface 112B and the two connecting Surfaces 112C may be uneven or stepped surfaces.

Each of the two electrode portions 112 may further include at least one recess 1121, and the recess 1121 may be disposed on the connecting surface 112C so that the connecting surface 112C becomes an uneven surface. The recess 1121 may increase the contact area between each of the electrode portions 112 and the housing 111 (the plastic body 150) and strengthen the fastening effect between each of the electrode portions 112 and the housing 111 by virtue of a geometric correspondence so that the binding force between each of the electrode portions 112 and the housing 111 is relatively strong. If there is a plurality of recesses 1121, the recesses 1121 may be designed with different dimensions according to different binding forces required at a different position between each of the electrode portions 112 and the housing 111.

The wing portion 112A, the inner side surface 112B and the two connecting surfaces 112C of the two electrode portions 112 may divide the at least one depletion region 130 into a plurality of depletion regions 130, that is, these depletion regions 130 may be respectively a gap 131, two first through grooves 132 and two second through grooves 133 in communication with each other. The gap 131 is disposed between the inner side surfaces 112B of the two electrode portions 112, and the two first through grooves 132 are disposed along the two connecting surfaces 112C of the two electrode portions 112. That is, one of the first through grooves 132 extends from an edge of a connecting surface 112C of one of the electrode portions 112 to an edge of a connecting surface 112C of the other one of the electrode portions 112 that face the same direction. The two first through grooves 132 are spaced apart from each other in terms of position.

The two second through grooves 133 are disposed along wing portions 112A of the two electrode portions 112. That is, one of the second through grooves 133 extends only along the wing portion 112A of one of the electrode portions 112. The two second through grooves 133 are also spaced apart from each other in terms of position.

The supporting portion 121 of the frame 120 may extend towards one of the two connecting surfaces 112C of the two electrode portions 112 into one of the two first through grooves 132. The housing 111 may be optionally disposed within the two first through grooves 132 and/or the gap 131. Additionally, the housing cross section 111A of the housing 111 may at least include a curved surface, e.g., may have a rounded corner 111R as shown in FIG. 12D. The housing cross section of the housing 111 has the rounded corner that is connected to the electrode portion cross section 112A2 of each of the electrode portions 112. The rounded corner 111R may disperse the impact force so that the rounded corner 111R is difficult to be broken or cracked by the impact force during a vibration test of the singulated carrier 110. Moreover, in the embodiment as shown in FIG. 12D, the housing cross section and the electrode portion cross section do not form a flat surface, i.e., the housing cross section is not aligned with the electrode portion cross section.

According to the above descriptions, the carrier frame 100′ may also allow the electrode portions 112 of the carriers 110 to be electrically isolated from each other. Thus, after the die bonding process, the wire bonding process and the packaging process are subsequently performed for the light emitting device, an electrical measurement may be directly performed for a non-singulated light emitting device, and this greatly improves the production speed of the light emitting device. It will be further appreciated that, the technical contents of the carrier frame 100′ may also be used as a reference for the carrier frame 100.

An embodiment of the present invention further provides a method for manufacturing a carrier frame, which may at least manufacture the aforesaid carrier frame 100′. The method for manufacturing the carrier frame 100′ is similar to the method for manufacturing the aforesaid carrier frame 100 and includes the following steps.

Reference may be made to FIG. 13A to FIG. 13C, where a conductive support 160 is first provided. The conductive support 160 includes a frame 120, and the frame 120 includes at least one supporting portion 121, at least one depletion region 130 and at least one extending portion 140. The at least one depletion region 130 may correspond to the gap 131, the two first through grooves 132 and the two second through grooves 133 of the carrier frame 100′, but at this point, the two first through grooves 132 have not been in communication with the two second through grooves 133 yet. The at least one extending portion 140 may correspond to the two electrode portions 112 of the carrier frame 100′, but at this point, the two electrode portions 112 have not been separated from the frame 120 yet.

Reference may be made to FIG. 14, where a plastic body 150 is then formed in a second step. The plastic body 150 covers at least a part of the extending portion 140 and at least a part of the supporting portion 121, and the plastic body 150 fills at least a part of the depletion region 130. For example, the plastic body 150 covers part of the two electrode portions 112 of the extending portions 140 and completely covers the supporting portion 121, and the plastic body 150 fills the gap 131 and the two first through grooves 132 of the depletion region 130 but does not fill the second through grooves 133. Furthermore, the plastic body 150 may be brought into contact with the recess 1121 (as shown in FIG. 13A) of the extending portion 140 so as to increase the contact area between the plastic body 150 and the extending portion 140.

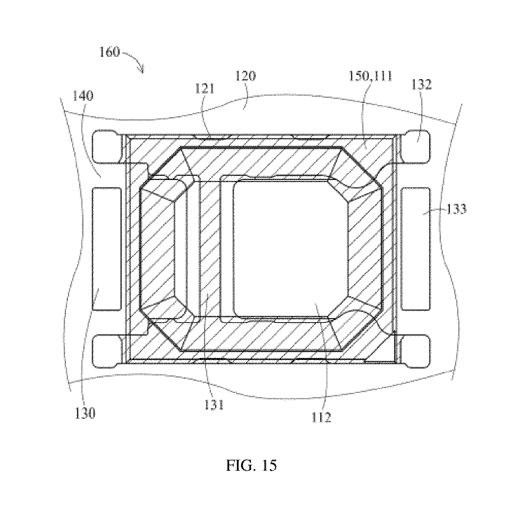

Reference may be made to FIG. 15, where a part of the plastic body 150 filled in the depletion region 130 is removed in a third step. That is, the part of the plastic body 150 filled in the two first through grooves 132 is removed. The plastic body 150 to be removed is called the residual material 151 (as shown in FIG. 14), and the scope of the residual material 151 is defined depending on the specific shape of the product. In this embodiment, the plastic body 150 filled in two end areas of the two first through grooves 132 is removed so that convex corners at four corners of the plastic body 150 are removed. The remaining plastic body 150 forms the housing 111 of the carrier frame 100′.

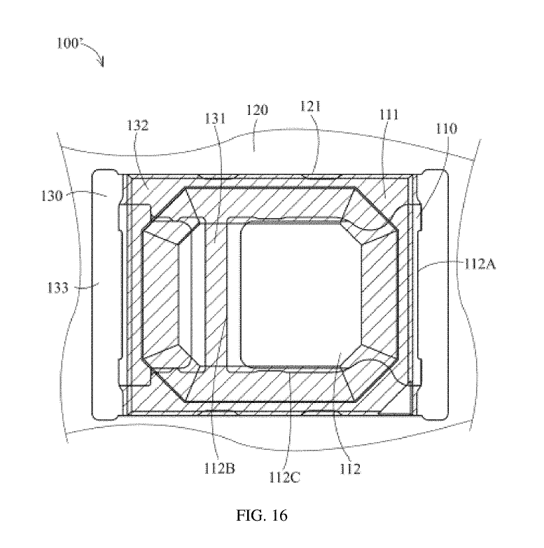

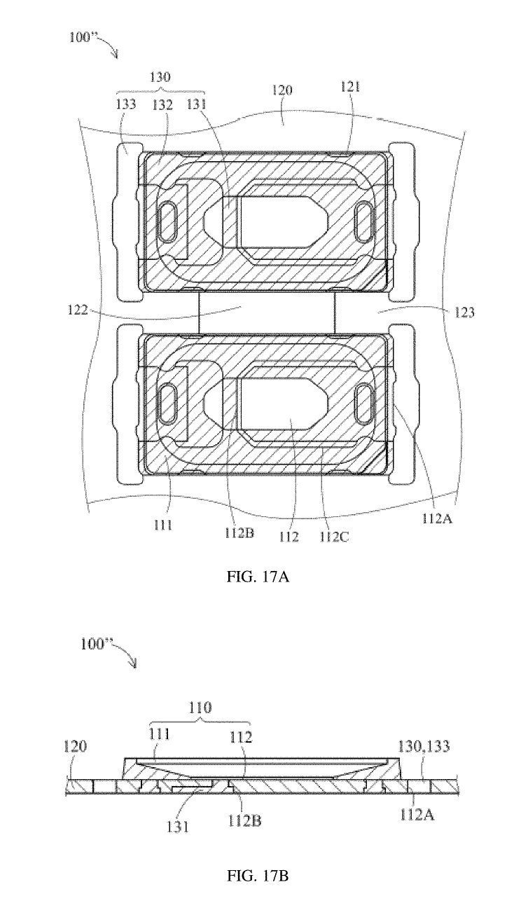

Reference may be made to FIG. 16, where a part of the extending portion 140 exposed outside the plastic body 150 is removed in a fourth step so that the remaining part of the extending portion 140 is separated from the frame 120. In other words, parts of extending portions 140 at two sides of the second through grooves 133 (as shown in FIG. 15) will be removed in this step so that the second through grooves 133 are in communication with the first through grooves 132. The remaining extending portions 140 form the electrode portions 112 of the carrier frame 100′.

After the aforesaid steps are completed, the carrier frame 100′ may be manufactured. For detailed technical contents of the aforesaid steps, reference may be made to the method for manufacturing the carrier frame 100. For example, a conductive layer may be firstly formed on the conductive support 160, the third step and the fourth step may be implemented in an interchangeable order, and the plastic body 150 may be cleaned before the fourth step is implemented, and the like.

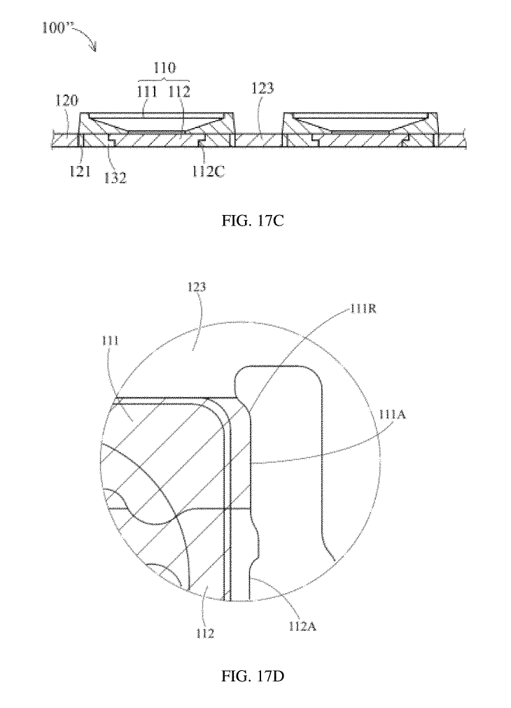

Reference may be made to FIG. 17A to FIG. 17D which are schematic views (i.e., a top view, a full cross-sectional view taken along the front-to-back direction, a full cross-sectional view taken along the left-to-right direction, and a partially enlarged view) of a carrier frame 100″ according to an embodiment of the present invention and which show more than one carrier frame 100″.

The carrier frame 100″ is similar to the aforesaid carrier frames 100 and 100′, so reference may be made to each other for their technical contents. However, it will be appreciated that, the frame 120 of the carrier frame 100″ has a side portion 123 and a channel region 122, and the side portion 123 may be shared by frames 120 of the two carrier frames 100″. In other words, the frames 120 of the two carrier frames 100″ may be formed integrally via the shared side portion 123. Moreover, carriers 110 of the two carrier frames 100″ are separated from each other by the side portion 123. The channel region 122 is disposed in the side portion 123 and is in communication with one of the two first through grooves 132 of each carrier frame 100″. It will be further appreciated that, the housing cross section 111A of the housing 111 may at least include a curved surface, e.g., may have a rounded corner 111R, and the rounded corner 111R is connected to the side portion 123 of the frame 120. Additionally, the electrode portion cross section of each of the electrode portions 112 may also at least include a curved surface, and the aforesaid curved surface is not limited to a single curvature. That is, the outline of the edge areas of each of the electrode portions 112 is a curved line. The electrode portion cross section is not adjacent to the rounded corner 111R. The impact force may be dispersed by means of the curved cross section. Meanwhile, in the embodiment as shown in FIG. 17D, the housing cross section and the electrode portion cross section do not form a flat surface, i.e., the housing cross section is not aligned with the electrode portion cross section.

In terms of the effect, the carrier frame 100″ may also allow the electrode portions 112 of each carrier 110 to be electrically isolated from each other. Thus, after the die bonding process, the wire bonding process and the packing process are subsequently performed for the light emitting device, an electric measurement may be directly performed for the non-singulated light emitting device, and this greatly improves the production speed of the light emitting device.

An embodiment of the present invention further provides a method for manufacturing a carrier frame, which can at least manufacture the aforesaid carrier frame 100″. The method for manufacturing the carrier frame 100″ is similar to the method for manufacturing the carrier lead frame 100′, and thus for the two manufacturing methods, identical technical contents will be omitted or simplified. The method for manufacturing the carrier lead frame 100″ may include the following steps.

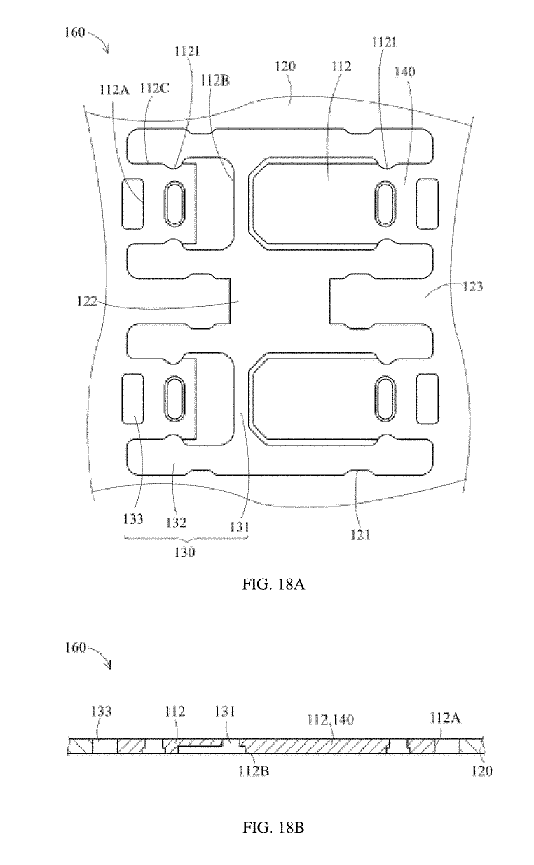

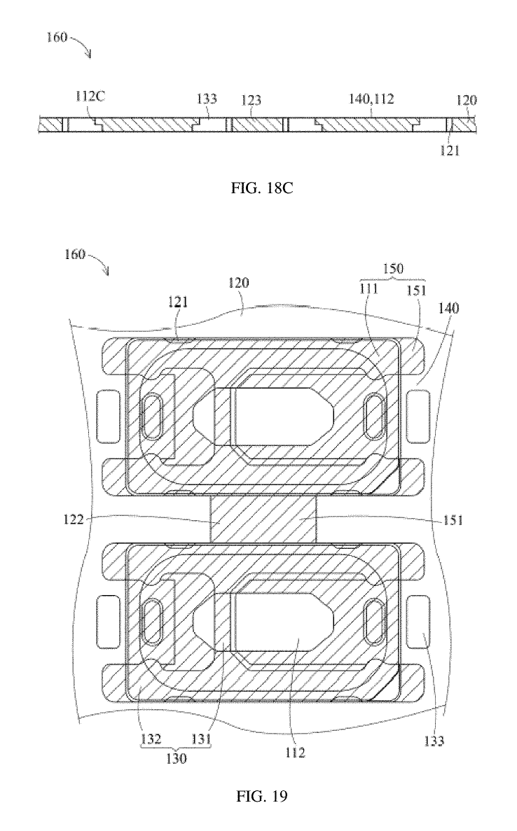

Reference may be made to FIG. 18A to FIG. 18C, where a conductive support 160 is first provided. This embodiment will be described by taking two conductive supports 160 as an example. Each of the conductive supports 160 includes at least one frame 120, and the frame body 120 includes at least one supporting portion 121, at least one side portion 123, at least one channel region 122, at least one depletion region 130 and at least one extending portion 140. The channel region 122 is disposed on the side portion 123 and is in communication with the depletion region 130.

Reference may be made to FIG. 19, where a plastic body 150 is then formed in a second step. The plastic body 150 covers at least a part of the extending portion 140 and at least a part of the supporting portion 121 of each conductive support 160, and the plastic body 150 fills at least a part of the depletion region 130. The plastic body 150 also fills the channel region 122; that is, the plastic body 150 passes through the channel region 122 to cover another conductive support 160. Moreover, the plastic body 150 is brought into contact with the recess 1121 (as shown in FIG.18A) of the extending portion 140 to increase the contact area between the plastic body 150 and the extending portion 140.

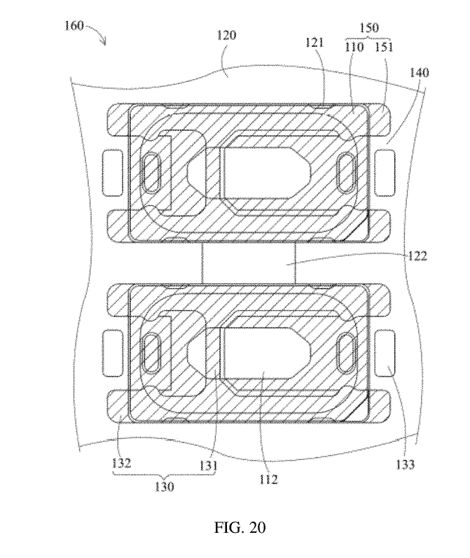

Reference may be made to FIG. 20, where the plastic body 150 filled in the channel region 122 is removed in a third step. The plastic body 150 may be removed in one step or in several steps. Specifically, if the plastic body 150 is removed in one step, then a cutter having a length larger than that of the channel region 122 will be used to remove the part of the frame 120 at two sides of the channel region 122 together with the plastic body 150 within the channel region 122. Thus, after the plastic body 150 within the channel region 122 is removed, the channel region 122 will be slightly elongated.

If the plastic body 150 is removed in several steps, a cutter having a length slightly smaller than that of the channel region 122 will first be used to remove a part of the plastic body 150 within the channel region 122, and then another cutter is used to remove the remaining plastic body 150 within the channel region 122 by means of actions such as scraping.

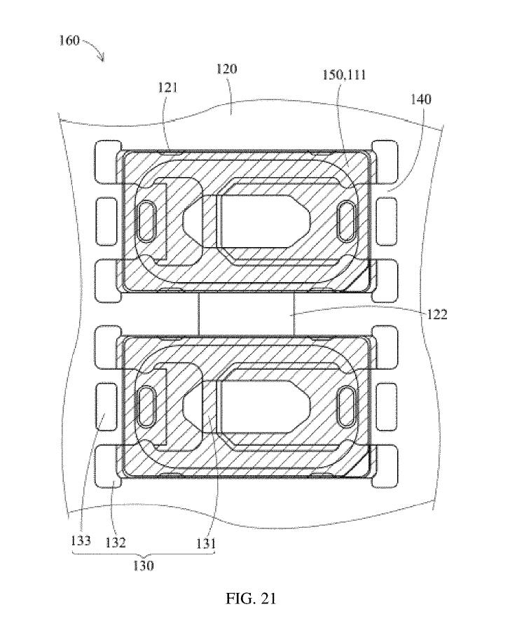

Reference may be made to FIG. 21, where a part of the plastic body 150 filled in the depletion region 130 is removed in a fourth step. That is, a part of the plastic body 150 filled in the two first through grooves 132 (e.g., the residual material 151 at the four corners as shown in FIG. 20) is removed. After the third step and the fourth step are completed, the remaining plastic body 150 that is not removed forms the housing 111 of the carrier frame 100″.

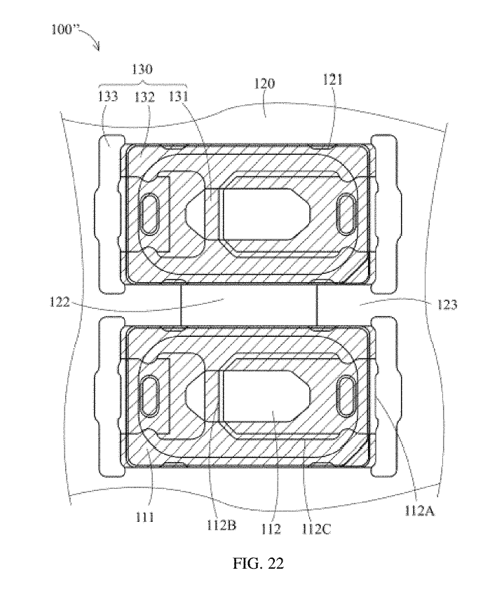

Reference may be made to FIG. 22, where a part of the extending portion 140 exposed outside the plastic body 150 (as shown in FIG. 21) is removed in a fifth step so that a remaining part of the extending portion 140 is separated from the frame 120. In other words, the part of the extending portion 140 at two sides of the second through groove 133 will be removed in this step so that the second through groove 133 is in communication with the first through groove 132. The remaining extending portion 140 forms the electrode portion 112 of 40 the carrier frame 100″.

After the aforesaid steps are completed, the carrier frame 100″ is manufactured. It shall be noted that, the third step to the fifth step may be implemented in an interchangeable order, which is not limited herein.

It should be noted that, relevant features about the material injection on the side wall (the plastic block 200) of the reflective concave cup 20, relevant features about the carrier including at least two conductive circuits, and relevant features about the reflective concave cup 20 having on its top surface the groove 202 for accommodating the adhesive are applicable not only to the carrier 100 but also to the carrier frame 100′ and the carrier frame 100″. For details, reference may be made to descriptions of the foregoing embodiments, and details will not be described herein again.

Although the above preferred embodiments have disclosed the present invention, they are not intended to limit the present invention. Any person skilled in the art can make some modifications and improvements without departing from the spirit and scope of the present invention. Therefore, the scope of the present invention is subject to the appended claims.

1. A carrier, comprising:
at least one electrode portion, each electrode portion having an electrode portion cross section; and
a housing having a housing cross section, the housing covering at least a part of the at least one electrode portion;
wherein the housing cross section or the electrode portion cross section at least comprises a curved surface;
a reflective concave cup for exposing a part of the electrode portion;
wherein the reflective concave cup has, on its outer side wall, at least a block protruding outward and matching a material feeding hole of a fabrication mold for fabricating the reflective concave cup.

2. The carrier according to claim 1, wherein the electrode portion comprises a central area and two edge areas, and the electrode portion cross section is located at the edge areas.

3. The carrier according to claim 1, wherein the housing cross section comprises a rounded corner.

4. The carrier according to claim 3, wherein the rounded corner is connected with the housing cross section.

5. The carrier according to claim 2, wherein the electrode portion cross section and the central area are not coplanar.

6. The carrier according to claim 1, wherein the block is located at the bottom of the outer side wall of the reflective concave cup.

7. The carrier according to claim 1, wherein the carrier comprises at least two conductive circuits, and the conductive circuits are electrically independent from each other;
each conductive circuit comprises a first electrode portion and a second electrode portion, and the first electrode portion comprises an accommodating region where the second electrode portion is located, and the first electrode portion is provided with a light emitting diode chip that is electrically connected to the first electrode portion and the second electrode portion, respectively.

8. The carrier according to claim 1, wherein at least one groove for accommodating adhesive is defined on a top surface of the reflective concave cup.

9. The carrier according to claim 8, wherein a depth of the groove is 0.1 mm.

10. A light emitting device, comprising:
the carrier according to claim 1; and
at least one light emitting diode chip that is disposed on the electrode portion and is located within the reflective concave cup.

11. A carrier, comprising:
at least one electrode portion, each electrode portion having an electrode portion cross section; and
a housing having a housing cross section, the housing covering at least a part of the at least one electrode portion;
wherein the housing cross section is not aligned with the electrode portion cross section;
a reflective concave cup for exposing a part of the electrode portion;
wherein the reflective concave cup has, on its outer side wall, at least one block protruding outward and matching a material feeding hole of a fabrication mold for fabricating the reflective concave cup.

12. The carrier according to claim 11, wherein the electrode portion has a central area and two edge areas, and the electrode portion cross section is located at the edge areas.

13. The carrier according to claim 12, wherein the central area is protruding from the edge areas.

14. The carrier according to claim 12, wherein the electrode portion cross section is a sloping surface.

15. The carrier according to claim 12, wherein the electrode portion cross section and the central area are not coplanar.

16. The carrier according to claim 11, wherein the block is located at the bottom of the outer side wall of the reflective concave cup.

17. The carrier according to claim 11, wherein the carrier comprises at least two conductive circuits, and the conductive circuits are electrically independent from each other;
each conductive circuit comprises a first electrode portion and a second electrode portion, the first electrode portion has an accommodating region where the second electrode portion is located, and the first electrode portion is provided with a light emitting diode chip that is electrically connected to the first electrode portion and the second electrode portion, respectively.

18. The carrier according to claim 11, wherein at least one groove for accommodating adhesive is defined on a top surface of the reflective concave cup.

19. The carrier according to claim 18, wherein a depth of the groove is 0.1 mm.

20. A light emitting device, comprising:
the carrier according to claim 11; and
at least one light emitting diode chip that is disposed on the electrode portion and is located within the reflective concave cup.
